(19) United States
(12) Patent Application Publication
(10) Pub. No.: US 2024/0021365 A1
(43) Pub. Date: Jan. 18, 2024

(54) ELECTRONIC COMPONENT, COIL COMPONENT, AND METHOD FOR MANUFACTURING ELECTRONIC COMPONENT

(71) Applicant: Murata Manufacturing Co., Ltd., Kyoto-fu (JP)

(72) Inventor: Keisuke KUNIMORI, Nagaokakyo-shi (JP)

(73) Assignee: Murata Manufacturing Co., Ltd., Kyoto-fu (JP)

(21) Appl. No.: 18/348,069

(22) Filed: Jul. 6, 2023

(30) Foreign Application Priority Data
Jul. 13, 2022 (JP) 2022-112746

(51) Int. Cl. H01F 41/04; H01F 27/32; H01F 27/28; H01F 41/12

(52) U.S. Cl. CPC H01F 41/041; H01F 27/32; H01F 27/2804; H01F 41/12

(57) ABSTRACT

An electronic component includes a second insulating layer laminated on a main surface of a first insulating layer in which a circuit pattern is embedded, so that stacking misalignment or step-off of a wiring layer is prevented without impairing electrical characteristics. An electronic component includes a first insulating layer having a main surface; a circuit pattern embedded in the first insulating layer and extending along a plane parallel to the main surface; and a second insulating layer laminated on the main surface. A section of the first insulating layer orthogonal to the main surface is an inverted trapezoid in which a length of a lower side opposite to the main surface is shorter than a length of an upper side on the main surface side.

### CROSS-REFERENCE TO RELATED APPLICATION

This application claims benefit of priority to Japanese Patent Application No. 2022-112746, filed Jul. 13, 2022, the entire content of which is incorporated herein by reference.

### BACKGROUND

### Technical Field

The present disclosure relates to an electronic component, a coil component, and a method for manufacturing an electronic component.

### Background Art

Conventionally, a coil component including a coil plated and grown on a substrate is known.

Japanese Patent Application Laid-Open No. 2020-047938 discloses a method for manufacturing a coil component in which a plurality of resin walls having an opening on a substrate is provided as insulating walls, and the coil is grown by plating so that a winding portion extends between the insulating walls, for the purpose of improving insulation properties of the coil.

In addition, Japanese Patent No. 6716866 discloses a coil component in which the insulating walls on the substrate as described above are formed in a tapered shape in which the width of the upper end portion is narrower than the width of the lower end portion to improve the strength of the winding portion.

### SUMMARY

In any of the coil components of the related art described above, only one layer of the winding portion is provided on one or both of the main surfaces of the substrate, and it is not disclosed that the coil is configured by laminating a plurality of layers of the winding portion on one main surface.

When two or more layers of the winding portion are to be formed on one main surface of the substrate, it is necessary to accurately align the insulating walls of the upper winding portion with respect to the lower winding portion. However, when the insulating walls of the upper layer are formed by photolithography, depending on the alignment accuracy of exposure, a positional deviation (stacking misalignment) between the layers may occur, and a “step-off” state in which a part of the upper winding portion falls on the substrate beyond the range of the upper surface of the lower winding portion may occur.

As a method of preventing such step-off, it is conceivable to configure each layer such that the lower surface of the upper winding portion is included within the range of the upper surface of the lower winding portion, that is, to make the width of the sectional shape of the upper winding portion narrower than the width of the sectional shape of the lower winding portion in the sectional view of the winding portion.

However, in order to achieve the above configuration, in order to make the width of the lower layer larger than the width of the upper layer, it may be necessary to increase the thickness of the insulating wall in the lower winding portion with respect to the insulating wall of the upper layer, to reduce the number of windings of the winding portion of the upper layer with respect to the lower winding portion, or to make the coil conductor thinner (for example, in a narrow width). As a result, electrical characteristics such as a decrease in inductance value or an increase in electrical resistance as a coil component may be deteriorated.

The stacking misalignment and the step-off caused when the layered wiring layer in which the circuit pattern is embedded in the insulating layer is stacked like the winding portion described above, and the decrease in the thickness of the insulating wall and the decrease in the number of conductors in the upper layer that can be caused to prevent the stacking misalignment and the step-off are not desirable in not only the coil component but also general electronic components.

Accordingly, the present disclosure prevents stacking misalignment or step-off of a wiring layer without impairing electrical characteristics in an electronic component including a second insulating layer laminated on a main surface of a first insulating layer in which a circuit pattern is embedded.

One aspect of the present disclosure is an electronic component including a first insulating layer having a main surface; a circuit pattern embedded in the first insulating layer and extending along a plane parallel to the main surface; and a second insulating layer laminated on the main surface. A section of the first insulating layer orthogonal to the main surface is an inverted trapezoid in which a length of a lower side opposite to the main surface is shorter than a length of an upper side on the main surface side.

Another aspect of the present disclosure is a method for manufacturing an electronic component, the method including a step of forming a circuit pattern extending along a plane; a step of forming a first insulating layer covering the circuit pattern and having a main surface parallel to the plane; and a step of laminating a second insulating layer on the main surface. In the step of forming the first insulating layer, a photosensitive resin is disposed so as to cover the circuit pattern, and the photosensitive resin is exposed and developed by irradiation light from a projection exposure apparatus set to off-focus with respect to a surface of the photosensitive resin, so that a section of the first insulating layer orthogonal to the main surface is formed in an inverted trapezoidal shape in which a length of a lower side opposite to the main surface is shorter than a length of an upper side on the main surface side.

Another aspect of the present disclosure is a method for manufacturing an electronic component, the method including a step of forming a plurality of insulating walls arranged in one direction in a plane; a step of forming a circuit pattern extending along the plane between the plurality of insulating walls; a step of forming an upper wall covering the insulating walls and the circuit pattern and having a main surface parallel to the plane; a step of laminating a second insulating layer on the main surface. In the step of forming the insulating walls, a photosensitive resin is disposed so as to cover the plane, and the photosensitive resin is exposed and developed by irradiation light from a projection exposure apparatus set to off-focus with respect to a surface of the photosensitive resin, so that a section of the insulating wall orthogonal to the plane is formed in a reverse tapered shape in which a width decreases from a side on which the second insulating layer is laminated toward an opposite side, and in which the insulating walls and the upper wall constitute a first insulating layer having an inverted trapezoidal shape in which a length of a lower side opposite to the main surface is shorter than a length of an upper side on the main surface side.

According to the present disclosure, it is possible to prevent stacking misalignment or step-off of the wiring layer without impairing electrical characteristics in the electronic component including the second insulating layer laminated on the main surface of the first insulating layer in which the circuit pattern is embedded.

### BRIEF DESCRIPTION OF THE DRAWINGS

FIG. 1 is a schematic view illustrating an internal structure of a coil component according to a first embodiment of the present disclosure;

FIG. 2 is a detailed view of a laminated body of the coil component illustrated in FIG. 1;

FIG. 3 is a view illustrating a manufacturing process of the laminated body illustrated in FIG. 2;

FIG. 4 is a view illustrating a manufacturing process subsequent to FIG. 3 of the laminated body illustrated in FIG. 2;

FIG. 5 is a view illustrating a configuration of a coil component according to a second embodiment;

FIG. 6 is a partial detailed view of a laminated body of the coil component illustrated in FIG. 5;

FIG. 7 is a view for describing a dimension definition of the laminated body illustrated in FIG. 6;

FIG. 8 is a view illustrating a manufacturing process of the laminated body illustrated in FIG. 7;

FIG. 9 is a view illustrating a manufacturing process subsequent to FIG. 8 of the laminated body illustrated in FIG. 7;

FIG. 10 is a view illustrating a configuration of a coil component according to a third embodiment;

FIG. 11 is a partial detailed view of a laminated body of the coil component illustrated in FIG. 10;

FIG. 12 is a view illustrating a manufacturing process of the laminated body illustrated in FIG. 11;

FIG. 13 is a view illustrating a manufacturing process subsequent to FIG. 12 of the laminated body illustrated in FIG. 11;

FIG. 14 is a view illustrating a configuration of a coil component according to a fourth embodiment;

FIG. 15 is a partial detailed view of a laminated body of the coil component illustrated in FIG. 14;

FIG. 16 is a view illustrating an example of a step of embedding the laminated bodies illustrated in FIG. 15 in a magnetic layer; and

FIG. 17 is a view illustrating a modification of the laminated body illustrated in FIG. 15.

### DETAILED DESCRIPTION

Hereinafter, embodiments of the present disclosure will be described with reference to the drawings.

In the following embodiment, a coil component will be described as an example of an electronic component including a laminated body in which insulating layers are laminated. The drawings may include schematic views at a part thereof. In addition, dimensions and ratios in the schematic views may be different from actual numerical values.

### First Embodiment

First, a first embodiment will be described.

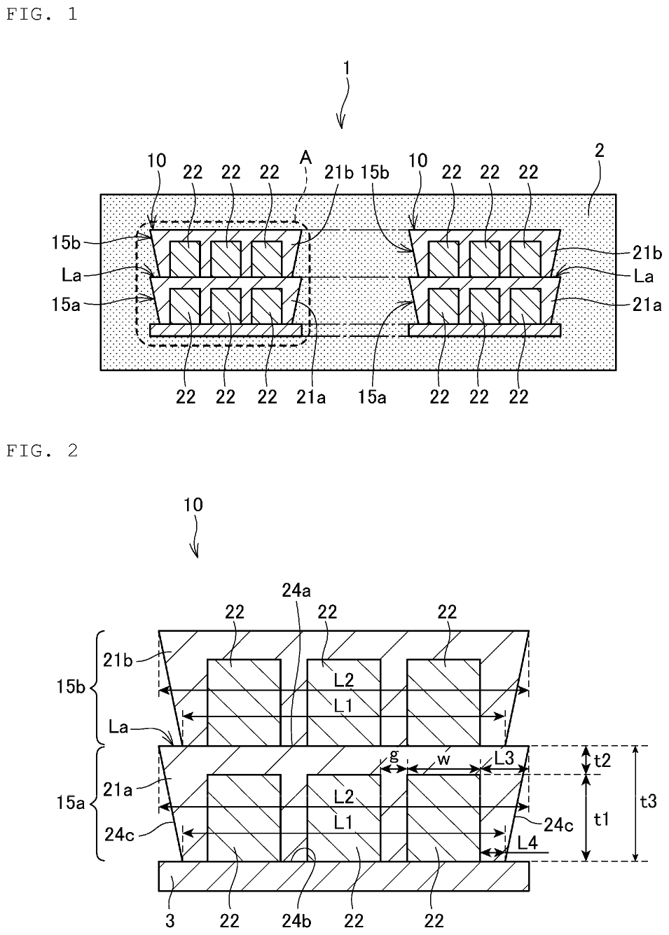

FIG. 1 is a schematic view illustrating an internal structure of a coil component 1 according to a first embodiment of the present disclosure.

The coil component 1 includes a first insulating layer 21a having a main surface La, circuit patterns 22 embedded in the first insulating layer 21a and extending along a plane parallel to the main surface La of the first insulating layer 21a, and a second insulating layer 21b laminated on the main surface La of the first insulating layer 21a. In the coil component 1, a wiring layer 15a in which the circuit patterns 22 are embedded in the first insulating layer 21a and a wiring layer 15b in which the circuit patterns 22 are embedded in the second insulating layer 21b are stacked to form a laminated body 10. The wiring layer 15a and the wiring layer 15b have a ring shape in plan view as viewed from above in the drawing, and parts of the circuit patterns 22 are connected to each other inside the laminated body 10 to form a coil portion. The circuit patterns 22 of the wiring layers 15a and 15b stacked in two layers extend in the same direction. In FIG. 1, the extending direction of the circuit patterns 22 is a normal direction on the paper. Therefore, FIG. 1 illustrates a section of the coil component 1 along a plane orthogonal to the extending direction of the circuit pattern 22. Hereinafter, the first insulating layer 21a and the second insulating layer 21b are also collectively referred to as an insulating layer 21, and the wiring layer 15a and the wiring layer 15b are also collectively referred to as a wiring layer 15.

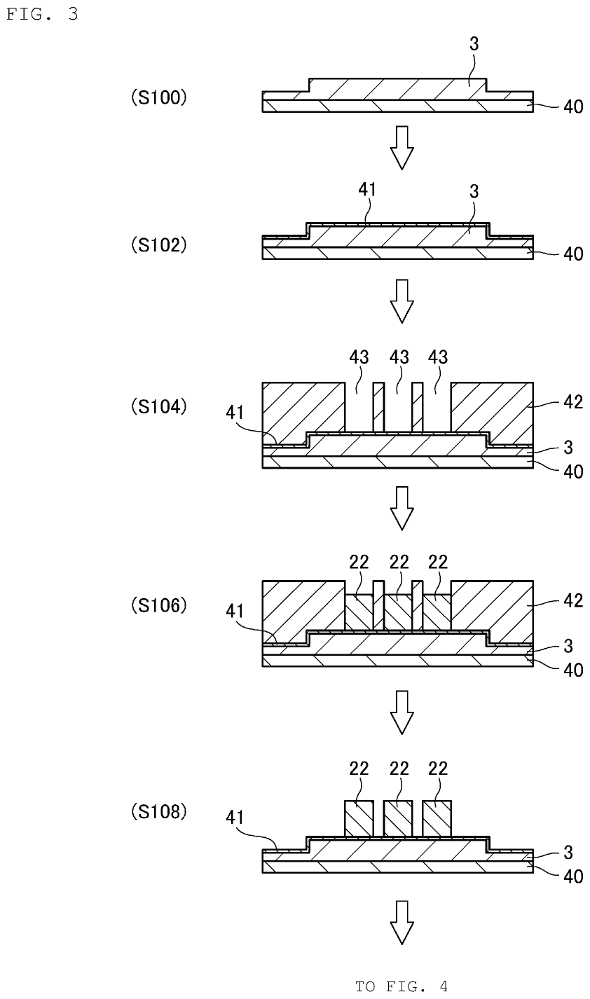

FIG. 2 is a partial detailed view of the laminated body 10 in the part A of FIG. 1, and illustrates a section of the first insulating layer 21a orthogonal to the main surface La of the first insulating layer 21a. The section is a section of the laminated body 10 along a plane orthogonal to the extending direction of the circuit pattern 22. Hereinafter, a section of the laminated body 10 along a plane orthogonal to the extending direction of the circuit pattern 22 is also referred to as a laminated body section. The laminated body section is a section including the central portion of the coil component 1.

The laminated body 10 includes two wiring layers 15 in which the circuit patterns 22 are embedded in the insulating layer 21, and these wiring layers 15 are stacked on a lower lid layer 3 in one direction.

In the laminated body 10, the main surface of each layer of the wiring layer 15 may include unevenness in its surface, or may include distortion in sectional view of a section including the lamination direction.

As illustrated in FIG. 2, in the present embodiment, in particular, the shape of the section of the first insulating layer 21a in the laminated body section of the laminated body 10 formed on the lower lid layer 3 is an inverted trapezoid in which a length L1 of a lower side 24b opposite to the main surface La is shorter than a length L2 of an upper side 24a on the main surface La side. The second insulating layer 21b on the upper side in the drawing is similarly configured. Here, two opposing sides connected to the end portion of the upper side 24a and the end portion of the lower side 24b are referred to as sides 24c.

With the above configuration, in the coil component 1, the margin of the arrangement of the wiring layer 15b on the upper side on the upper surface of the wiring layer 15a on the lower side is secured as (L1-L2). Therefore, in the manufacturing process of the coil component 1, it is possible to effectively prevent occurrence of stacking misalignment and step-off of the wiring layer 15b on the upper side with respect to the wiring layer 15a on the lower side.

In addition, in the coil component 1, instead of laminating the wiring layers in a pyramid shape with the size of the wiring layer on the upper side being smaller than that of the wiring layer on the lower side, each of the wiring layers 15 can be formed in the same sectional shape and the same size as illustrated in FIG. 2. That is, the section of the second insulating layer 21b along the laminated body section is an inverted trapezoid in which the length L1 of the lower side on the first insulating layer 21a side is shorter than the length L2 of the upper side on the opposite side to the first insulating layer 21a side. Therefore, in the coil component 1, it is not necessary to increase the amount of the insulating layer 21 between the circuit patterns 22 of the wiring layer 15a on the lower side with respect to the wiring layer 15b on the upper side, or to reduce the number of the circuit patterns 22 of the wiring layer 15b on the upper side with respect to the wiring layer 15a on the lower side, or to narrow the width of the circuit pattern 22. In addition, in the coil component 1, since the section (therefore, the section of the wiring layer 15) of the insulating layer 21 has an inverted trapezoidal shape, for example, as compared with a conventional configuration in which the section of the wiring layer is a rectangle having the width L2, the volume of the magnetic layer 2 embedding the laminated body 10 can be increased, so that the inductance value as the coil component 1 can be improved.

That is, in the coil component 1, it is possible to prevent the stacking misalignment and the step-off of the wiring layers 15 at the time of forming the laminated body 10 without impairing the electrical characteristics such as the inductance value and the electrical resistance. As a result, in the coil component 1, good characteristics can be stably realized with a high manufacturing yield.

As an example, the width w of the circuit pattern 22 is 5 μm or more and 100 μm or less (i.e., from 5 μm to 100 μm), the thickness t1 of the circuit pattern 22 is 5 μm or more and 100 μm or less (i.e., from 5 μm to 100 μm), and the distance g between the circuit patterns 22 is 5 μm or more and 30 μm or less (i.e., from 5 μm to 30 μm). In addition, for example, the thickness t2 of the insulating layer 21 above the circuit pattern 22 is 5 μm or more and 40 μm or less (i.e., from 5 μm to 40 μm), and the thickness t3 of the insulating layer 21 is 10 μm or more and 140 μm or less (i.e., from 10 μm to 140 μm).

In addition, for one or both of the two sides 24c of the inverted trapezoid formed by the section of the first insulating layer 21a, a first distance L3 measured along the upper side 24a from the portion (that is, the circuit pattern 22 at the right end in the drawing) of the circuit pattern 22 closest to the side 24c (for example, the first lateral side on the right side in the drawing) to the upper end of the side 24c and a second distance L4 measured along the lower side 24b from the portion of the circuit pattern 22 closest to the side 24c to the lower end of the side 24c are preferably set to a range that satisfies the following Formulas (1) and (2).

5 μm≤L4≤20 μm (1)

1.1≤L3/L4≤1.5 (2)

Note that, in FIGS. 2, L3 and L4 are defined at the end portion on the right side in the drawing of the wiring layer 15 on the upper side in the drawing, but L3 and L4 can be similarly defined at the end portion on the left side in the drawing, and it is more preferable that the conditions illustrated in Formulas (1) and (2) are applied. The same applies to the wiring layer on the upper side in the drawing.

In Formula (1), when the length L4 of the lower side is less than 5 μm, close contact property between the wiring layer 15 and a layer which is adjacent to and below the wiring layer 15 is weak, and insulation may be deteriorated. In addition, when the length L4 of the lower side is larger than 20 μm, a significant decrease in the inductance value can be recognized due to a decrease in the volume of the magnetic layer 2 covering the laminated body 10.

In addition, in a case where L4 is the lower limit value 5 μm in Formula (1), the value of L3 corresponding to the lower limit value 1.1 in Formula (2) is 5.5 μm, and the allowable error of the arrangement of the wiring layer 15 on the upper side with respect to the wiring layer 15 on the lower side is 0.5 μm (=L3-L4) in one of the left and right directions. This allowable error is a value assuming alignment accuracy of a general mask aligner used in a photolithography step when the wiring layer 15 is formed. Accordingly, when the alignment accuracy of the mask aligner to be used is greater than 0.5 μm, the lower limit value of Formula (2) can be adjusted accordingly.

In the above description, when there is a step or unevenness on the upper surface of the first insulating layer 21a, the length L2 of the upper side 24a of the section of the first insulating layer 21a can be measured as the maximum width of the portion of interest in plan projection view of the first insulating layer 21a viewed from above. Similarly, the length L4 can be measured in plan projection view. In addition, in a case where each of L1, L2, L3, and L4 changes along the extending direction of the circuit pattern 22, each of L1, L2, L3, and L4 can be an average value in a section including the portion of interest by a predetermined distance (for example, 1 mm) or more along the extending direction of the circuit pattern 22. The same applies to measurement of dimensions in the second insulating layer 21b and other embodiments described later.

The laminated body 10 of the coil component 1 can be manufactured as follows.

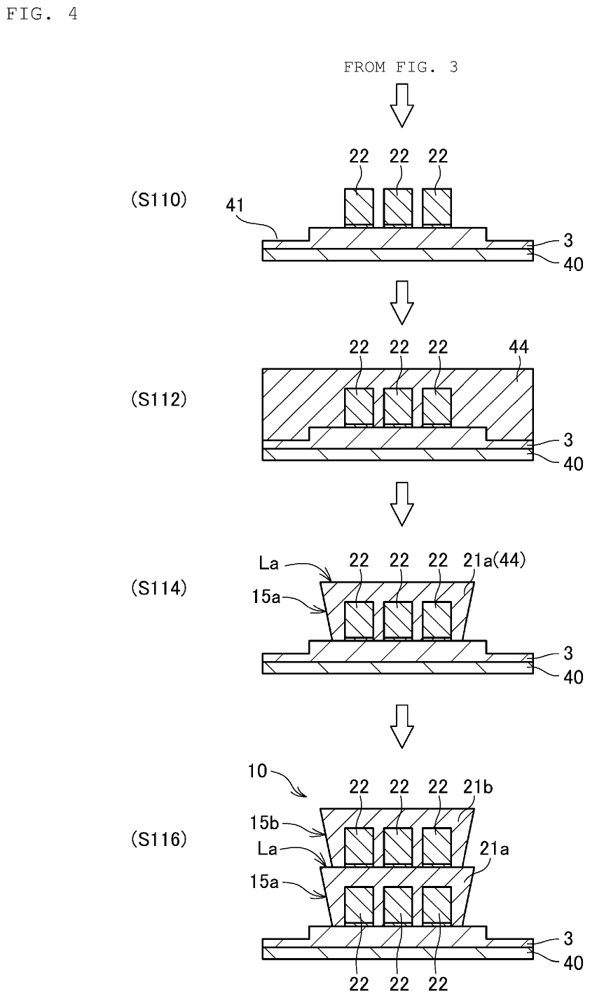

FIGS. 3 and 4 are views illustrating a manufacturing process of the laminated body 10.

In FIG. 3, first, a resin is applied onto a flat substrate 40 to form the lower lid layer 3 (S100), and the seed layer 41 is formed on the flat surface of the lower lid layer 3 (S102). The substrate 40 is, for example, a flat ceramic plate. In addition, the seed layer 41 is a feed film made of copper metal for performing plating growth by a semi additive process (SAP), and can be formed by sputtering or electroless plating.

Next, a resist 42 is applied onto the seed layer 41, and patterning is performed using photolithography to provide openings 43 for forming the circuit patterns 22 (S104). Subsequently, copper metal is grown by plating in the openings 43 by electrolytic plating to form the circuit patterns 22 (S106), and the resist 42 is removed (S108).

Referring to FIG. 4, next, the seed layer 41 is removed by etching (S110). Here, steps S102 to S110 correspond to a step of forming the circuit pattern 22 extending along the plane in the present disclosure.

Next, under a vacuum heating environment, an insulating dry film 44 which is a photosensitive resin to be the insulating layer 21 is pressed against the substrate 40, and the circuit patterns 22 are covered so that the insulating dry film 44 is filled in gaps between the circuit patterns 22 (S112). The insulating dry film 44 is a so-called photosensitive permanent film or a permanent resist, and is a negative type in the present embodiment.

Subsequently, by patterning using photolithography, other portions of the insulating dry film 44 are removed while leaving a portion covering the circuit pattern 22 (S114). As a result, the first insulating layer 21a having the main surface La parallel to the surface of the lower lid layer 3 is formed by the insulating dry film 44 which is a photosensitive resin subjected to exposure development. Here, steps S112 and S114 correspond to a step of forming the first insulating layer 21a that covers the circuit patterns 22 and has the main surface La parallel to the plane on which the circuit patterns 22 are formed in the present disclosure.

In the photolithography step in step S114, in particular, a projection exposure apparatus is set to off-focus with respect to the surface of the insulating dry film 44. In the present embodiment, specifically, the focal point of the projection exposure apparatus is set away from the surface of the insulating dry film 44 (that is, by shifting from the surface in the upward direction in the drawing,). As a result, the insulating dry film 44 left on the lower lid layer 3 after development has an inverted trapezoidal section as illustrated in FIG. 4. When the insulating dry film 44 is a positive type, a similar inverted trapezoidal section can be formed by shifting the focus position of the projection exposure apparatus in the internal direction of the insulating dry film 44 (that is, by shifting in the downward direction in the drawing from the surface).

In general, a focus position of an exposure machine in photolithography is usually set with high accuracy on a surface of a photosensitive resin such as a resist from the viewpoint of performing high-accuracy patterning. On the other hand, in the present embodiment, by intentionally setting the focal position of the projection exposure apparatus to off-focus with respect to the surface of the insulating dry film 44, the insulating dry film 44 having an inverted trapezoidal section is left on the lower lid layer 3 as the first insulating layer 21a by subsequent exposure and development.

As a result, the section of the first insulating layer 21a orthogonal to the main surface La is formed in an inverted trapezoidal shape in which the length of the lower side opposite to the main surface La is shorter than the length of the upper side on the main surface La side.

Subsequently, the second insulating layer 21b of the wiring layer 15b as a second layer is laminated on the main surface La of the first insulating layer 21a by repeating the above-described steps S102 to S114 on the upper surface of the formed wiring layer 15a to form the laminated body 10 (S116). Here, when the wiring layer 15b as a second layer is formed, the section of each of the two insulating layers 21 is formed in an inverted trapezoidal shape in which the length of the lower side is shorter than the length of the upper side on the lower lid layer 3, and thus, as described above, the occurrence of the stacking misalignment and the step-off of the wiring layer 15b of the second layer (upper side) with respect to the wiring layer 15a of the first layer (lower side) is prevented.

### Second Embodiment

Next, a second embodiment of the present disclosure will be described.

FIG. 5 is a view illustrating a configuration of the coil component 4 according to the second embodiment. In FIG. 5, the same components as those of the coil component 1 illustrated in FIG. 1 are denoted by the same reference numerals as those in FIG. 1, and the description of FIG. 1 described above is incorporated. The coil component 4 has the same configuration as the coil component 1, but is different in that a laminated body 50 is provided instead of the laminated body 10. Similarly to the laminated body 10, the laminated body 50 is formed in a ring shape in plan view as viewed from above in the drawing.

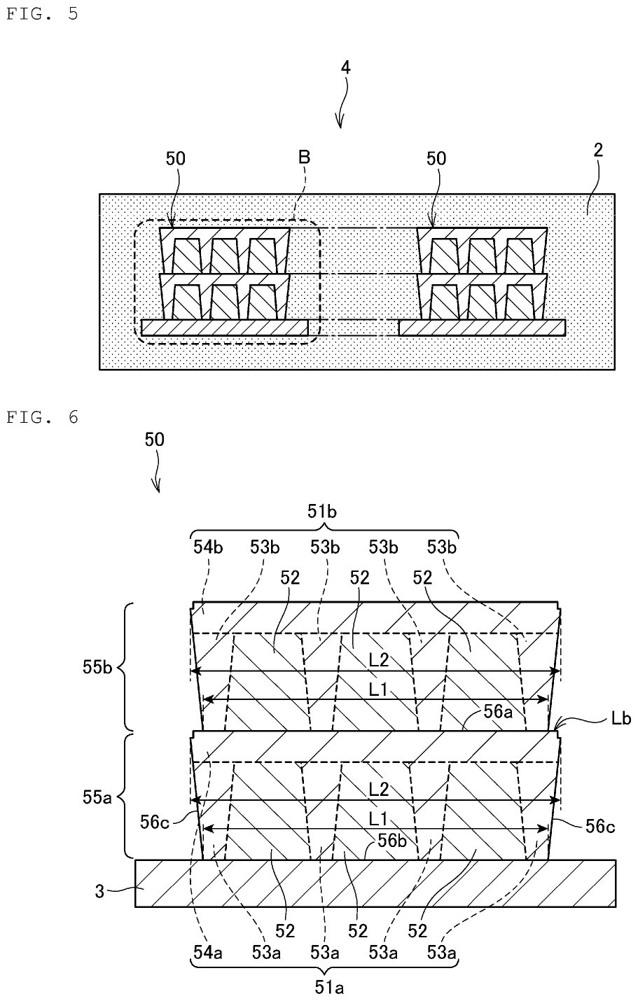

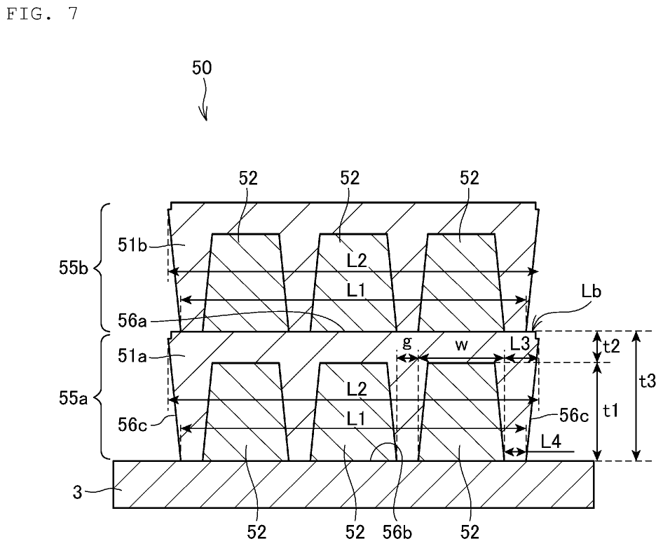

FIG. 6 is a partial detailed view of the laminated body 50 in the B part of FIG. 5, and is a view corresponding to FIG. 2 illustrating the configuration of the laminated body 10. In FIG. 6, the same components as those of the laminated body 10 illustrated in FIG. 2 are denoted by the same reference numerals as those in FIG. 2, and the description of FIG. 2 described above is incorporated.

The laminated body 50 illustrated in FIG. 6 has two wiring layers 55a and 55b stacked on a lower lid layer 3. The wiring layer 55a includes a first insulating layer 51a having a main surface Lb and circuit patterns 52 embedded in the first insulating layer 51a. The wiring layer includes a second insulating layer 51b laminated on the main surface Lb of the first insulating layer 51a, and circuit patterns 52 buried in the second insulating layer 51b. Similarly to the first insulating layer 21a, a section of the first insulating layer 51a has an inverted trapezoidal shape in which a length L1 of the lower side 56b is shorter than a length L2 of the upper side 56a.

The first insulating layer 51a has insulating walls 53a that sandwich the circuit patterns 52 along the direction of the lower side 56b of the inverted trapezoid formed by the section, and an upper wall 54a that covers the circuit patterns 52. In particular, all of the insulating walls 53a have a section of a reverse tapered shape in which the width decreases along the direction toward the lower lid layer 3, that is, the direction from the upper side 56a toward the lower side 56b. The circuit pattern 52 is located between the insulating walls 53a having a reverse tapered shape, and has a sectional shape of a trapezoidal shape whose width increases along the direction toward the lower lid layer 3. The second insulating layer 51b has insulating walls 53b corresponding to the insulating walls 53a and an upper wall 54b corresponding to the upper wall 54a, and has the same shape as the first insulating layer 51a. Hereinafter, the wiring layer 55a and the wiring layer 55b are also collectively referred to as a wiring layer 55, and the first insulating layer 51a and the second insulating layer 51b are also collectively referred to as an insulating layer 51. In addition, the insulating wall 53a and the insulating wall 53b are also collectively referred to as an insulating wall 53, and the upper wall 54a and the upper wall 54b are also collectively referred to as an upper wall 54.

In the manufacturing process, the insulating layer 51 having the shape as described above can be formed by forming all of the plurality of insulating walls 53 in a reverse tapered shape at a time by off-focus setting of the projection exposure apparatus as described above, and then plating and growing the circuit patterns 52 between the insulating walls 53. As described above, in the laminated body 50, since the insulating walls 53 of the insulating layer 51 can be formed in advance before the formation of the circuit patterns 52, high close contact property between the insulating walls 53 and the component below the insulating walls 53 (in the first insulating layer 51a, the lower lid layer 3 below the first insulating layer 51a, and in the second insulating layer 51b, the first insulating layer 51a below the second insulating layer 51b) can be secured, and insulation between the circuit patterns 52 can be enhanced.

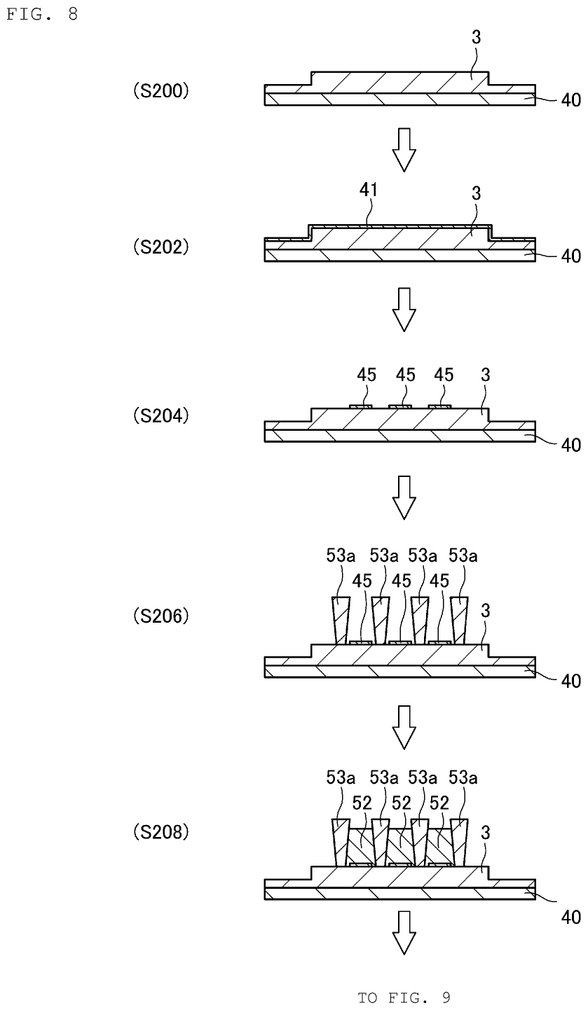

As illustrated in FIG. 7, for the wiring layer 55, similarly to the wiring layer 15 illustrated in FIG. 2, the thickness t1 of the circuit pattern 52, the interval g between the circuit patterns 52, the thickness t2 of the insulating layer 51 above the circuit pattern 52, and the thickness t3 of the insulating layer 51 can be defined. In addition, similarly to the insulating layer 21 illustrated in FIG. 2, for one or both of sides 56c of the inverted trapezoid shape formed by the section of the insulating layer 51, a first distance L3 from the circuit pattern 52 closest to a side 56c to the upper end of the side 56c measured along the upper side 56a and a second distance L4 to the lower end of the side 56c measured along the lower side 56b can be defined. Specific examples of these dimensions and preferable conditions are the same as those of the above-described insulating layer 21.

The laminated body 50 can be manufactured as follows.

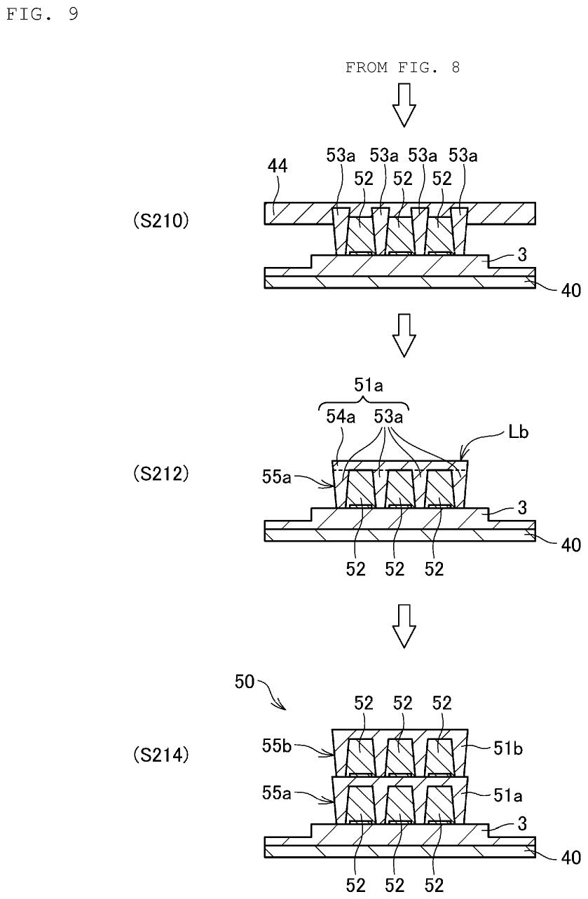

FIGS. 8 and 9 are views illustrating a manufacturing process of the laminated body 50. In FIGS. 8 and 9, the same components as those in FIGS. 3 and 4 are denoted by the same reference numerals as those in FIGS. 3 and 4, and the description of FIGS. 3 and 4 described above is incorporated.

In FIG. 8, first, a resin is applied onto a flat substrate 40 to form the lower lid layer 3 (S200), and a seed layer 41 which is a copper metal layer for plating growth is formed on a flat surface of the lower lid layer 3 (S202).

Next, the seed layer 41 is patterned by photolithography to form seed patterns 45 (S204). Subsequently, similarly to steps S112 and S114 in FIG. 4 described above, an insulating dry film as a photosensitive resin is pressed and brought into close contact with the seed patterns 45, and then the insulating dry film is patterned by photolithography. As a result, the insulating walls 53a extending along the seed patterns 45 are formed at positions sandwiching the seed patterns 45 on the surface of the lower lid layer 3 (S206).

Here, in step S206, similarly to step S114 in FIG. 4 described above, the projection exposure apparatus is set to off-focus during a photolithography step. As a result, the sections of all the insulating walls 53a are formed in a reverse tapered shape in which the width decreases from the side of the main surface Lb on which the second insulating layer 51b is stacked toward the opposite side in the subsequent step.

Subsequently, copper metal is grown by plating between the adjacent insulating walls 53a by electrolytic plating to form the circuit patterns 52 having a trapezoidal section (S208).

Referring to FIG. 9, next, an insulating dry film 44 is pressed and brought into close contact so as to cover the insulating walls 53a and the circuit patterns 52 (S210), and then an unnecessary portion of the insulating dry film 44 is removed by photolithography to form the upper wall 54a, and the wiring layer 55a as a first layer is formed on the lower lid layer 3 (S212). As a result, the upper wall 54a covering the insulating walls 53a and the circuit patterns 52 and having the main surface Lb parallel to the plane formed by the surface of the lower lid layer 3 is formed. The insulating walls 53a and the upper wall 54a having a reverse tapered shape constitute the first insulating layer 51a having an inverted trapezoidal shape in which the length of the lower side opposite to the main surface Lb is shorter than the length of the upper side on the main surface Lb side.

Subsequently, the wiring layer 55b is formed on the formed wiring layer 55a by repeating the above-described steps S202 to S212 on the upper surface of the formed wiring layer 55, thereby forming the laminated body 50 (S214).

Here, in the steps illustrated in FIGS. 8 and 9, step S206 corresponds to a step of forming a plurality of insulating walls arranged in one direction in a plane, and step 208 corresponds to a step of forming a circuit pattern extending along the plane between the plurality of insulating walls. Steps S210 and S212 correspond to a step of forming an upper wall covering the insulating walls and the circuit pattern and having a main surface parallel to a plane, and step S214 corresponds to a step of laminating a second insulating layer on the main surface.

### Third Embodiment

Next, a third embodiment of the present disclosure will be described.

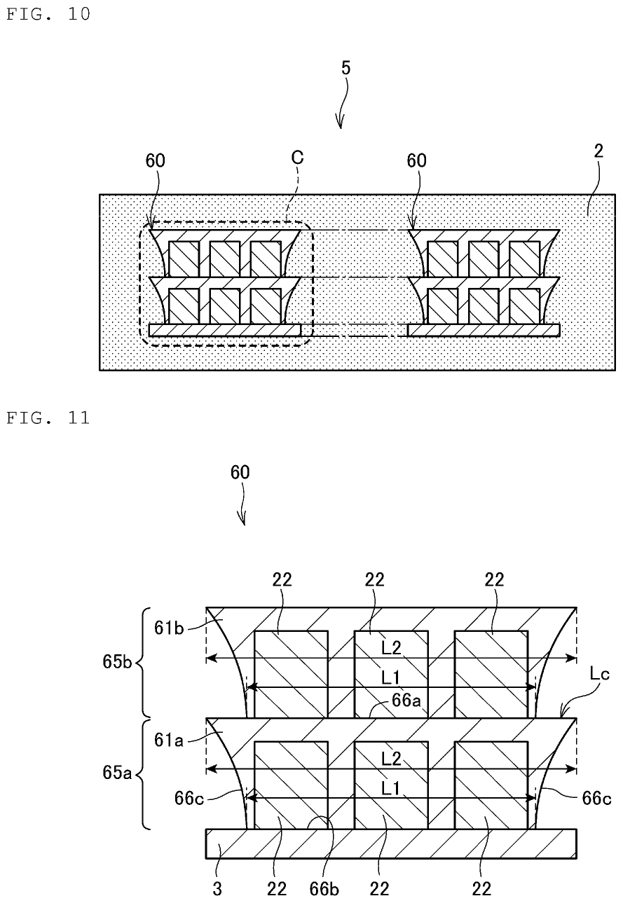

FIG. 10 is a view illustrating a configuration of a coil component 5 according to the third embodiment of the present disclosure. In FIG. 10, the same components as those of the coil component 1 illustrated in FIG. 1 are denoted by the same reference numerals as those in FIG. 1, and the description of FIG. 1 described above is incorporated. The coil component 5 has the same configuration as the coil component 1, but is different in that a laminated body 60 is provided instead of the laminated body 10. Similarly to the laminated body 10, the laminated body 60 is formed in a ring shape in plan view as viewed from above in the drawing.

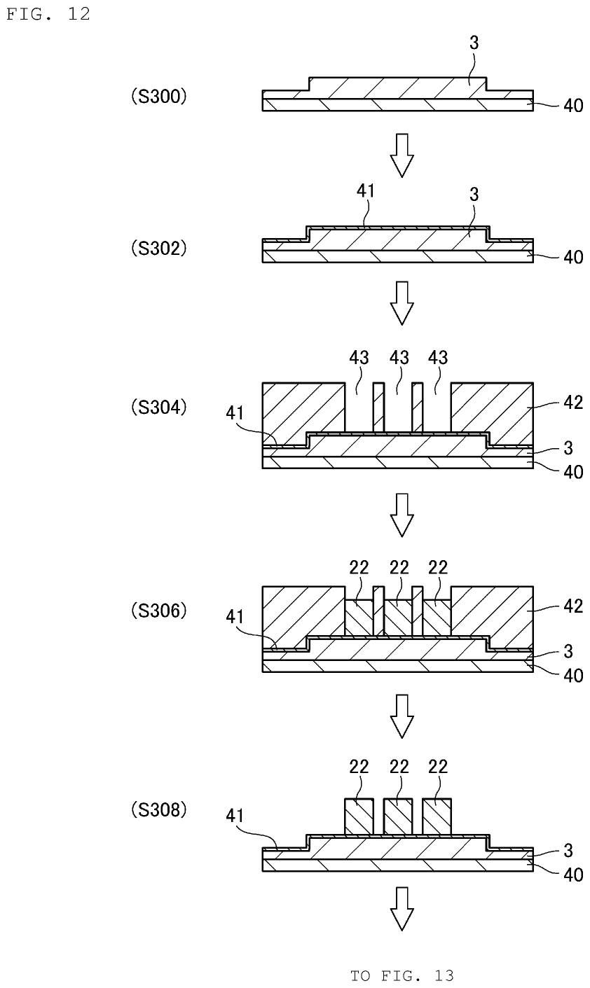

FIG. 11 is a partial detailed view of the laminated body 60 in the C part of FIG. 10, and is a view corresponding to FIG. 2 illustrating the configuration of the laminated body 10. In FIG. 11, the same components as those in FIG. 2 are denoted by the same reference numerals as those in FIG. 2, and the description of FIG. 2 described above is incorporated.

The laminated body 60 illustrated in FIG. 11 has the same configuration as the laminated body 10 illustrated in FIG. 2, but is different in that two wiring layers 65a and 65b stacked on the lower lid layer 3 are provided instead of the wiring layers 15a and 15b. The wiring layer 65a has the same configuration as the wiring layer 15a, but includes a first insulating layer 61a instead of the first insulating layer 21a. The first insulating layer 61a has the same configuration as the first insulating layer 21a, but has a sectional shape different from that of the first insulating layer 21a. Specifically, the sectional shape of the first insulating layer 61a is a substantially trapezoidal shape in which a length L2 of the upper side 66a on a main surface Lc side of a first insulating layer 61a is shorter than a length L1 of a lower side 66b, and each of two sides 66c forms an arcuate curve recessed toward the inside of the first insulating layer 61a.

The wiring layer 65b has the same configuration as the wiring layer 15b, but includes a second insulating layer 61b having the same configuration as the first insulating layer 61a described above instead of the second insulating layer 21b. Hereinafter, the first insulating layer 61a and the second insulating layer 61b are also collectively referred to as an insulating layer 61, and the wiring layer 65a and the wiring layer 65b are also collectively referred to as a wiring layer 65.

With the above-described configuration, in the coil component 5 using the laminated body 60, an additional space in which the magnetic layer 2 enters is secured in the recessed portion formed by the side of the insulating layer 61, so that the volume of the magnetic layer 2 can be increased to improve the inductance value as the coil component 5 as compared with the case of using the insulating layer 21 having no recess as illustrated in FIG. 2.

In the laminated body 60, the two left and right sides of the inverted trapezoidal shape formed by the section of the insulating layer 61 are curved in the present embodiment, but may be formed of a polygonal line forming a recess toward the inside of the insulating layer 61. Also in this case, the magnetic layer 2 enters into the recessed shape of the side constituted by the polygonal line, so that the inductance value of the coil component 5 can be improved.

The laminated body 60 can be manufactured as follows.

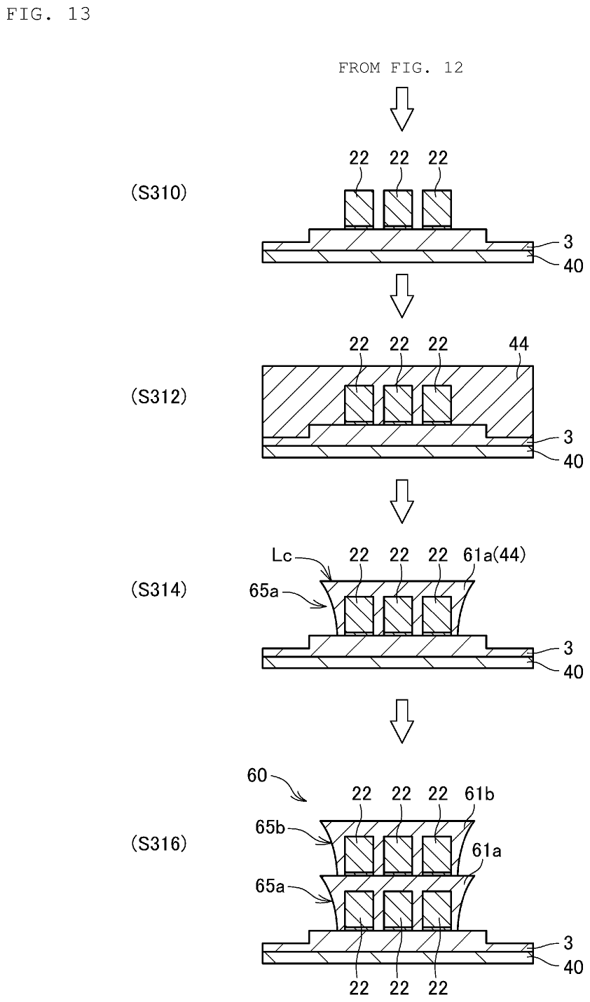

FIGS. 12 and 13 are views illustrating a manufacturing process of the laminated body 60. Note that, in FIGS. 12 and 13, the same components as those in FIGS. 3 and 4 are denoted by the same reference numerals as those in FIGS. 3 and 4, and the description of FIGS. 3 and 4 will be incorporated.

Steps S300 to S308 illustrated in FIG. 12 and steps S310 and S312 illustrated in FIG. 13 are similar to steps S100 to S108 illustrated in FIG. 3 and steps S110 and S112 illustrated in FIG. 4, respectively, and thus the description of FIGS. 3 and 4 described above is incorporated.

In step S314 of FIG. 13, similarly to step S114 described above, a projection exposure apparatus is set to off-focus, and patterning using photolithography is performed, thereby removing the other portions of the insulating dry film 44 while leaving a portion covering circuit patterns 22. However, in step S314, in particular, the exposure amount in the photolithography is set to be smaller than the exposure amount in step S114. As a result, an overdeveloped state is created in a development step subsequent to an exposure step in the photolithography, and a recessed shape is formed on a side surface portion of the patterned insulating dry film 44. As a result, the wiring layer 65 as a first layer is formed on the lower lid layer 3.

Subsequently, by repeating steps S302 to S314 on the upper surface of the formed wiring layer 65, the wiring layer 65 as a second layer is formed on the main surface Lc of the first insulating layer 61a of the formed wiring layer 65, and the laminated body 60 is formed (S316).

### Fourth Embodiment

Next, a fourth embodiment of the present disclosure will be described.

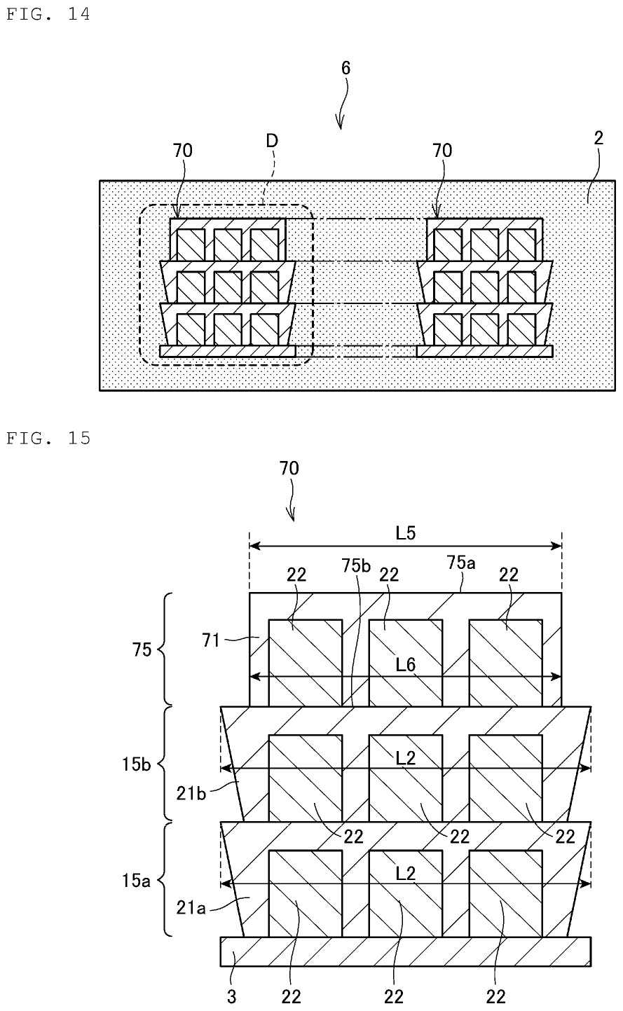

FIG. 14 is a view illustrating a configuration of a coil component 6 according to the fourth embodiment of the present disclosure. In FIG. 14, the same components as those of the coil component 1 illustrated in FIG. 1 are denoted by the same reference numerals as those in FIG. 1, and the description of FIG. 1 described above is incorporated. The coil component 6 has the same configuration as the coil component 1, but is different in that a laminated body is provided instead of the laminated body 10. Similarly to the laminated body 10, the laminated body 70 is formed in a ring shape in plan view as viewed from above in the drawing.

FIG. 15 is a partial detailed view of the laminated body 70 in the part D of FIG. 14, and is a view corresponding to FIG. 2 illustrating the configuration of the laminated body 10. In FIG. 15, the same components as those of the laminated body 10 illustrated in FIG. 2 are denoted by the same reference numerals as those in FIG. 2, and the description of FIG. 2 described above is incorporated.

The laminated body 70 illustrated in FIG. 15 has the same configuration as the laminated body 10 illustrated in FIG. 2, but further has a third insulating layer 71 laminated on the uppermost layer above a second insulating layer 21b farthest from a lower lid layer 3. The third insulating layer 71 and circuit patterns 72 embedded in the third insulating layer 71 constitute a wiring layer 75. The third insulating layer 71 has the same configuration as the insulating layer 21, but has a sectional shape different from that of the insulating layer 21. That is, in the section of the third insulating layer 71 along the section of the first insulating layer 21a, a length L5 of an upper side 75a on the opposite side to the second insulating layer 21b is the same rectangle as a length L6 of a lower side 75b on the second insulating layer 21b side.

In the laminated body 70 having the above configuration, since the sectional shape of the third insulating layer 71 of the wiring layer 75 which is the uppermost layer is not an inverted trapezoidal shape like the wiring layer 15 but a rectangle, embedding in a magnetic layer 2 is facilitated in a manufacturing process of the coil component 6.

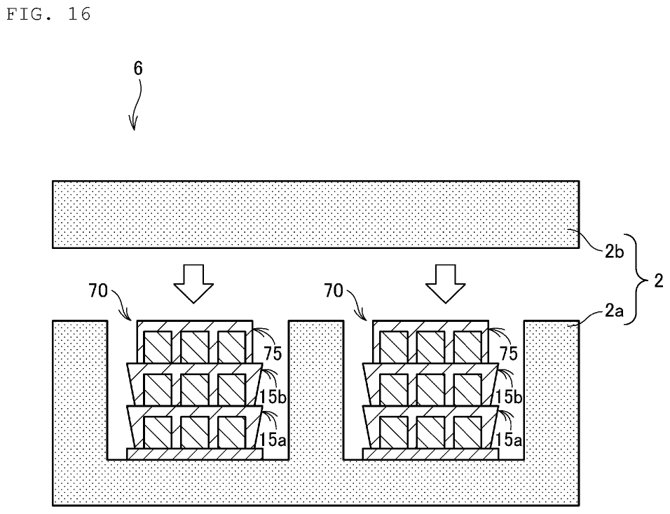

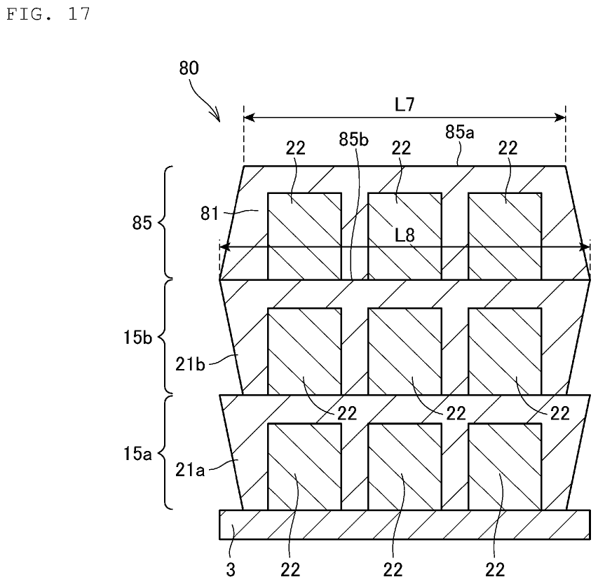

FIG. 16 is a view illustrating an example of a step of embedding the laminated bodies in the magnetic layer 2 at the time of manufacturing the coil component 6. For example, after the laminated bodies 70 are inserted into openings of a magnetic pellet 2a having an E-shaped section, a magnetic pellet 2b having an I-shaped section is pressurized and melted in the direction of the outlined arrows from the upper side in the drawing, so that the magnetic pellets 2a and 2b are embedded in the magnetic layer 2. Note that the step of embedding the laminated bodies 70 in the magnetic layer 2 is not limited to the above, and for example, a sheet-like material containing a magnetic powder in a resin may be disposed so as to sandwich the laminated bodies 70 from above and below the laminated bodies 70, and the laminated bodies 70 may be embedded in the magnetic layer 2 formed by the sheet by heat-pressing the sheet.

At this time, since the section of the third insulating layer 71 of the wiring layer 75, which is the uppermost layer of the laminated body 70, is not an inverted trapezoid but a rectangle, the magnetic pellet 2b pressurized and melted from above in the drawing easily forms a flow along the outer surface of the laminated body 70, and can easily flow into the gap between the magnetic pellet 2a and the laminated body 70 in the opening of the magnetic pellet 2a. Therefore, in the coil component 6 using the laminated body 70, voids (foam-like spaces) are less likely to occur between the laminated body 70 and the magnetic layer 2, and manufacturing variations in inductance values are less likely to occur.

In addition, in the case of using the laminated body 70, as illustrated in FIG. 15, the length L5 of the upper side 75a and the length L6 of the lower side 75b of the third insulating layer 71 of the wiring layer 75, which is the uppermost layer, are made shorter than the length L2 of the upper side of the insulating layer 21 of the wiring layer 15 below the third insulating layer 71, so that the volume of the magnetic layer 2 can be increased and the inductance value of the coil component 6 can be further improved as compared with the configuration in which all the wiring layers are the wiring layers 15.

Note that the section of the wiring layer as an uppermost layer of the laminated body is not limited to a rectangle but may be a trapezoid.

FIG. 17 is a view illustrating a configuration of a laminated body 80 as a modification of the laminated body 70, and is a view corresponding to FIG. 15 illustrating a configuration of the laminated body 70. The laminated body 80 can be used for the coil component 6 instead of the laminated body 70. In FIG. 17, the same components as those of the laminated body 70 illustrated in FIG. 15 are denoted by the same reference numerals as those in FIG. 15, and the description of FIG. 15 described above is incorporated.

The laminated body 80 illustrated in FIG. 17 has the same configuration as the laminated body 70, but is different in that a wiring layer 85 is provided in the uppermost layer instead of the wiring layer 75. The wiring layer 85 has the same configuration as the wiring layer 75, but is different in that a third insulating layer 81 is provided instead of the third insulating layer 71. The third insulating layer 81 has the same configuration as the third insulating layer 71, but its sectional shape is a trapezoid in which a length L7 of an upper side is shorter than a length L8 of a lower side 85b.

In the laminated body 80 having the above configuration, for example, when the laminated body 80 is embedded in the magnetic layer 2 by the step illustrated in FIG. 16, the magnetic pellet 2b pressed and melted can easily slide down the side of the trapezoidal section of the wiring layer 85 located at the uppermost layer. For this reason, the laminated body 80 is more easily embedded in the magnetic layer 2 when manufacturing the coil component as compared with the laminated body 70, and generation of voids in the magnetic layer 2 can be further suppressed.

### Other Embodiments

The laminated bodies 10, 50, 60, 70, and 80 each have two wiring layers 15, 55, or 65 in the above-described embodiments, but may have three or more layers.

In addition, in the above-described embodiments, the coil components 1, 4, 5, and 6 are illustrated as an example of an electronic component having a laminated body, but the electronic component on which the present disclosure can be implemented can be any electronic component other than the coil component, including a laminated body having a sectional structure similar to that of the laminated body 10, 50, 60, 70, or 80 in a part thereof. The plan view of such a laminated body is not limited to the ring shape, and may have any shape depending on the circuit design in the electronic component.

Further, in the first embodiment described above, the laminated body section, that is, the section of the first insulating layer 21a including the center portion of the coil component and orthogonal to the main surface La of the first insulating layer 21a is not particularly limited, but the sectional shape of the first insulating layer 21a may be an inverted trapezoid in at least one laminated body section. In the section of the first insulating layer 21a orthogonal to the laminated body section, the section of the first insulating layer 21a may be a rectangle in which the length of the upper side 24a is the same as the length of the lower side 24b, or a trapezoid in which the length of the upper side 24a is shorter than the length of the lower side 24b. However, the sectional shape of the first insulating layer 21a is more preferably an inverted trapezoid in any angle of the laminated body section including the central portion of the coil component and orthogonal to the main surface La of the first insulating layer 21a. The same applies to other embodiments.

In addition, the circuit patterns 22 and 52 constitute the coil portion in the above-described embodiments, but the configurations of the circuit patterns 22 and 52 are not limited thereto. The circuit patterns 22 and 52 may have a spiral shape, a circling shape of less than 1 turn, a linear shape, a meander shape, or the like.

In addition, the characteristic configurations illustrated in the above-described embodiments and modifications can be used in combination with each other in any electronic component. For example, the electronic component may include any combination of any number of laminated bodies having the same configurations as the laminated bodies 10, 50, 60, and 80 described above. Alternatively, the electronic component may include a laminated body in which any number of wiring layers having the same configuration as the wiring layers 55, 65, 75, and 85 described above are arbitrarily combined.

Note that all the above-described embodiments and modifications exemplify one aspect of the present disclosure, and modifications and applications can be arbitrarily made without departing from the gist of the present disclosure.

The directions such as horizontal and vertical directions, various numerical values, shapes, and materials in the above-described embodiments include a range (so-called equivalent range) in which the same functions and effects as those of the directions, numerical values, shapes, and materials are exhibited unless otherwise specified.

### Configurations Supported by Above Embodiments

The above-described embodiments and modifications support the following configurations.

(Configuration 1) An electronic component including a first insulating layer having a main surface; a circuit pattern embedded in the first insulating layer and extending along a plane parallel to the main surface; and a second insulating layer laminated on the main surface, in which a section of the first insulating layer orthogonal to the main surface is an inverted trapezoid in which a length of a lower side opposite to the main surface is shorter than a length of an upper side on the main surface side.

In the electronic component of the configuration 1, since the first insulating layer is formed in an inverted trapezoidal shape, it is possible to prevent stacking misalignment and step-off of the second insulating layer stacked thereon.

(Configuration 2) The electronic component according to the configuration 1, in which a section of the second insulating layer along the section of the first insulating layer is an inverted trapezoid in which a length of a lower side on the first insulating layer side is shorter than a length of an upper side opposite to the first insulating layer side.

In the electronic component of the configuration 2, since the stacked insulating layers can be configured to have the same section, it is not necessary to narrow the width of the insulating layer in the upper layer in order to avoid stacking misalignment and step-off of the insulating layer, and thus, there is no restriction such as narrowing the width of the circuit pattern in the upper layer. Therefore, according to the electronic component of the configuration 2, it is possible to prevent the stacking misalignment and the step-off of the wiring layer without impairing the electrical characteristics.

(Configuration 3) The electronic component according to the configuration 1 or 2, in which two opposing sides of the inverted trapezoid formed by the section of the first insulating layer and connected to an end portion of the upper side and an end portion of the lower side form a curved line or a polygonal line recessed toward an inside of the first insulating layer.

According to the electronic component of the configuration 3, when the laminated body is embedded in an electric material such as a magnetic body, an additional space for the electric material to enter can be secured in the recess formed on the side of the insulating layer, so that the electric characteristics of the electronic component can be improved.

(Configuration 4) The electronic component according to any one of the configurations 1 to 3, in which the first insulating layer includes insulating walls sandwiching the circuit pattern along a direction of the lower side of the inverted trapezoid formed by the section of the first insulating layer, and in which a section of the insulating wall in the section of the first insulating layer has a reverse tapered shape in which a width decreases along a direction from the upper side toward the lower side.

According to the electronic component of the configuration 4, for example, before the formation of the circuit pattern in the manufacturing process, all of the plurality of insulating walls are formed in a reverse tapered shape at a time by off-focus setting of a projection exposure apparatus, and the final section of the entire insulating layer can be formed in an inverted trapezoidal shape. As described above, according to the electronic component of the configuration 3, since the insulating walls can be formed before the circuit patterns are formed, the insulation between the circuit patterns can be enhanced.

(Configuration 5) The electronic component according to any one of the configurations 1 to 4, in which a ratio of a second distance to a first distance is greater than or equal to 1.1 and less than 1.5 (i.e., from 1.1 to less than 1.5), and the second distance is greater than or equal to 5 μm and less than or equal to 20 μm (i.e., from 5 μm to 20 μm), for a first side that is one of two opposing sides connected to an end portion of the upper side and an end portion of the lower side of the inverted trapezoid formed by the section of the first insulating layer, the first distance being measured along the upper side from a portion of the circuit pattern closest to the first side to an upper end of the first side, and the second distance being measured along the lower side from a portion of the circuit pattern closest to the first side to a lower end of the first side.

According to the electronic component of the configuration 5, it is possible to form a laminated body without stacking misalignment or step-off between wiring layers by using a mask aligner having general alignment accuracy used in a photolithography step.

(Configuration 6) The electronic component according to any one of the configurations 1 to 5, further including a third insulating layer laminated on an uppermost layer above the second insulating layer, in which a section of the third insulating layer along the section of the first insulating layer is a rectangle in which a length of an upper side opposite to the second insulating layer is the same as a length of a lower side on the second insulating layer side, or a trapezoid in which the length of the upper side is shorter than the length of the lower side.

According to the electronic component of the configuration 6, when the laminated body is embedded in an electric material such as a magnetic body, the flow of the electric material on the outer surface of the laminated body is facilitated, and a good embedded state without voids can be easily realized.

(Configuration 7) A coil component which is the electronic component according to any one of the configurations 1 to 5, in which the circuit pattern constitutes a coil.

According to the coil component of the configuration 7, it is possible to prevent the stacking misalignment and the step-off of the wiring layer without impairing the electrical characteristics such as the inductance value and the electrical resistance, and to stably realize good characteristics with a high manufacturing yield.

(Configuration 8) A method for manufacturing an electronic component, the method including a step of forming a circuit pattern extending along a plane; a step of forming a first insulating layer covering the circuit pattern and having a main surface parallel to the plane; and a step of laminating a second insulating layer on the main surface. In the step of forming the first insulating layer, a photosensitive resin is disposed so as to cover the circuit pattern, and the photosensitive resin is exposed and developed by irradiation light from a projection exposure apparatus set to off-focus with respect to a surface of the photosensitive resin, so that a section of the first insulating layer orthogonal to the main surface is formed in an inverted trapezoidal shape in which a length of a lower side opposite to the main surface is shorter than a length of an upper side on the main surface side.

According to the method for manufacturing an electronic component of the configuration 8, the electronic component described in the configuration 1 can be easily manufactured.

(Configuration 9) A method for manufacturing an electronic component, the method including a step of forming a plurality of insulating walls arranged in one direction in a plane; a step of forming a circuit pattern extending along the plane between the plurality of insulating walls; a step of forming an upper wall covering the insulating walls and the circuit pattern and having a main surface parallel to the plane; and a step of laminating a second insulating layer on the main surface.

In the step of forming the insulating walls, a photosensitive resin is disposed so as to cover the plane, and the photosensitive resin is exposed and developed by irradiation light from a projection exposure apparatus set to off-focus with respect to a surface of the photosensitive resin, so that a section of the insulating wall orthogonal to the plane is formed in a reverse tapered shape in which a width decreases from a side on which the second insulating layer is laminated toward an opposite side, and in which the insulating walls and the upper wall constitute a first insulating layer having an inverted trapezoidal shape in which a length of a lower side opposite to the main surface is shorter than a length of an upper side on the main surface side.

According to the method for manufacturing an electronic component of the configuration 9, the electronic component described in the configuration 4 can be easily manufactured.

What is claimed is:

1. An electronic component comprising:
a first insulating layer having a main surface;
a circuit pattern embedded in the first insulating layer and extending along a plane parallel to the main surface; and
a second insulating layer laminated on the main surface,
wherein a section of the first insulating layer orthogonal to the main surface is an inverted trapezoid in which a length of a lower side opposite to the main surface is shorter than a length of an upper side on the main surface side.

2. The electronic component according to claim 1, wherein
a section of the second insulating layer along the section of the first insulating layer is an inverted trapezoid in which a length of a lower side on the first insulating layer side is shorter than a length of an upper side opposite to the first insulating layer side.

3. The electronic component according to claim 1, wherein
the inverted trapezoid defined by the section of the first insulating layer includes two opposing sides connected to end portions of the upper side and end portions of the lower side, and
the two opposing sides define a curved line or a polygonal line recessed toward an inside of the first insulating layer.

4. The electronic component according to claim 1, wherein
the first insulating layer includes insulating walls sandwiching the circuit pattern along a direction of the lower side of the inverted trapezoid defined by the section of the first insulating layer, and
a section of the insulating wall in the section of the first insulating layer has a reverse tapered shape in which a width of the insulating wall decreases along a direction from the upper side toward the lower side.

5. The electronic component according to claim 1, wherein
a ratio of a second distance to a first distance is from 1.1 to less than 1.5, and
the second distance is from 5 μm to 20 μm,
a first side is defined one of two opposing sides connected to an end portion of the upper side and an end portion of the lower side of the inverted trapezoid defined by the section of the first insulating layer,
the first distance being measured along the upper side from a portion of the circuit pattern closest to the first side to an upper end of the first side, and
the second distance being measured along the lower side from a portion of the circuit pattern closest to the first side to a lower end of the first side.

6. The electronic component according to claim 1, further comprising:
a third insulating layer laminated on an uppermost layer above the second insulating layer,
wherein
a section of the third insulating layer along the section of the first insulating layer is a rectangle in which a length of an upper side of the third insulating layer which is opposite to the second insulating layer is the same as a length of a lower side of the third insulating layer on the second insulating layer side, or
the section of the third insulating layer is a trapezoid in which the length of the upper side thereof is shorter than the length of the lower side thereof.

7. A coil component which is the electronic component according to claim 1, wherein
the circuit pattern configures a coil.

8. A coil component which is the electronic component according to claim 2, wherein
the circuit pattern configures a coil.

9. A coil component which is the electronic component according to claim 3, wherein
the circuit pattern configures a coil.

10. A coil component which is the electronic component according to claim 4, wherein
the circuit pattern configures a coil.

11. A coil component which is the electronic component according to claim 5, wherein
the circuit pattern configures a coil.

12. A coil component which is the electronic component according to claim 6, wherein
the circuit pattern configures a coil.

13. A method for manufacturing an electronic component, the method comprising:
forming a circuit pattern extending along a plane;
forming a first insulating layer covering the circuit pattern and having a main surface parallel to the plane; and
laminating a second insulating layer on the main surface of the first insulating layer,
wherein in the forming of the first insulating layer,
a photosensitive resin is disposed to cover the circuit pattern, and
the photosensitive resin is exposed by irradiation light from a projection exposure apparatus set to off-focus with respect to a surface of the photosensitive resin and developed, so that a section of the first insulating layer orthogonal to the main surface is converted in an inverted trapezoidal shape in which a length of a lower side opposite to the main surface is shorter than a length of an upper side on the main surface side.

14. A method for manufacturing an electronic component, the method comprising:
forming a plurality of insulating walls arranged in one direction in a plane;
forming a circuit pattern extending along the plane between the plurality of insulating walls;
forming an upper wall covering the insulating walls and the circuit pattern and having a main surface parallel to the plane; and
laminating a second insulating layer on the main surface of the upper wall,
wherein in the forming of the insulating walls,
a photosensitive resin is disposed to cover the plane, and
the photosensitive resin is exposed by irradiation light from a projection exposure apparatus set to off-focus with respect to a surface of the photosensitive resin and developed, so that a section of the insulating wall orthogonal to the plane is formed in a reverse tapered shape in which a width of the insulating wall decreases from a side on which the second insulating layer is laminated toward an opposite side, and
wherein the insulating walls and the upper wall configure a first insulating layer having an inverted trapezoidal shape in which a length of a lower side opposite to the main surface is shorter than a length of an upper side on the main surface side.
